(19) United States
(12) Patent Application Publication
(10) Pub. No.: US 2024/0422915 A1
(43) Pub. Date: Dec. 19, 2024

(54) CLOUD COMPUTING AND INTERNET OF THINGS-BASED MONITORING TECHNIQUES USING CUSTOM DEVICES

(71) Applicant: CDW LLC, Vernon Hills, IL (US)

(72) Inventor: Donald L. Doyle, II, Fenton, MI (US)

(21) Appl. No.: 18/378,813

(22) Filed: Oct. 11, 2023

Related U.S. Application Data
(60) Provisional application No. 63/472,999, filed on Jun. 14, 2023.

(51) Int. Cl. H04L 67/12; G06F 1/16; H05K 1/18

(52) U.S. Cl. CPC H05K 1/181; G01R 1/203; G01R 31/371; H04W 88/16; H05K 2201/10159

(57) ABSTRACT

An Internet-of-Things battery shunt device includes a shunt member and an outer housing the outer housing comprising a circuit board. An IoT gateway device includes a circuit board comprising a microcontroller; an I2C interface and a memory. A computing system includes a remote computing device; an electronic network; an IoT gateway device; and an IoT battery shunt device coupled to the IoT gateway device and a vehicle battery; the IoT gateway device includes instructions for causing the IoT gateway device to receive physical data from the IoT battery shunt device; process the physical data; and transmit the physical data to the remote computing device. A computing system includes a remote gateway device configured to read sensor data; an electronic database; a processors; a memory configured to receive data; process the data; and cause the processed data to be stored.

### CROSS-REFERENCE TO RELATED APPLICATIONS

This application claims priority to U.S. Provisional Application No. 63/472,999, entitled CLOUD COMPUTING AND INTERNET OF THINGS-BASED MONITORING TECHNIQUES USING CUSTOM DEVICES, filed on Jun. 14, 2023, which is incorporated herein by reference in its entirety.

### TECHNICAL FIELD

The present disclosure is generally directed to methods and systems for cloud computing and internet-of-things-based monitoring and managing of devices using custom hardware devices, and more particularly, to techniques for monitoring health of internet-of-things resources using customized devices that receive and transmit sensor information.

### BACKGROUND

Conventional monitoring and managing techniques are deficient for several reasons. Such mechanisms lack predictive capabilities. For example, current battery monitoring and management techniques are not able to accurately predict battery failure or performance decline. In general, current techniques perform simple temperature/current (amperage) monitoring, which only provides rudimentary indications of battery health/performance. Such techniques cannot provide state of charge or state of health information sufficient to enable actionable or preemptive steps to be taken. Further, existing battery monitoring and management approaches lack real-time monitoring capabilities. Batteries are only checked periodically, if at all, and failures or declines in performance that occur between checks are unavoidable.

Further, conventional techniques do not consider the differences between battery technologies. Yet the cost of battery replacement is high, running to the thousands of dollars per battery and hundreds of dollars in labor costs. Batteries are often replaced too frequently, or not frequently enough. Similar deficiencies are true in other areas besides batteries.

Therefore, there is an opportunity for improved management and monitoring platforms, that employ more sophisticated techniques to deliver more timely, accurate and comprehensive monitoring, across a range of device types, leading to more efficient use of device resources and longer lifespans.

### BRIEF SUMMARY

In one aspect, an Internet-of-Things (IoT) battery shunt device includes a shunt member and an outer housing, the shunt member having two protruding wings each having respective annular opening through which battery wires may be passed, and the outer housing comprising: a circuit board comprising: an analog-to-digital converter (ADC) circuit for converting an analog signal to current measured in amperage; a thermal resistor circuit for measuring temperature; an ADC circuit for measuring voltage at rest and voltage at load; and a header for transmitting the current, the temperature and the voltage.

In another aspect, an Internet-of-Things (IoT) gateway device includes a circuit board comprising: one or more microcontroller units; one or more inter-integrated circuit (I2C) interfaces for receiving information; and a memory having stored thereon instructions that, when executed by the one or more microcontroller units, cause the system to: receive, via the one or more processors, at least one set of one or more electro-physical measurements from at least one sensor via at least one of the I2C interfaces; process the electro-physical measurements; and transmit the electro-physical measurements to a remote computing device via an electronic network.

In yet another aspect, a computing system for collecting state of health and/or state of charge of one or more vehicle batteries includes a remote computing device; an electronic network; an IoT gateway device comprising at least one microcontroller unit and one or more memories; and one or more IoT battery shunt devices, wherein each IoT battery shunt device is communicatively coupled to the IoT gateway device via a respective annular opening in the housing of the IoT gateway device, and wherein each IoT battery shunt device is communicatively coupled to a respective one of the vehicle batteries; wherein the one or more memories of the IoT gateway device include computer-executable instructions that, when executed by the at least one microcontroller unit of the IoT gateway device, cause the IoT gateway device to: receive, from the IoT gateway device via the electronic network physical data from at least one of the IoT battery shunt devices; process, via the one or more processors, the physical data; and transmit, via the electronic network, the physical data to the remote computing device.

In still further aspects, a computing system for monitoring state of health and/or state of charge of one or more remote devices includes one or more remote gateway devices configured to read sensor data from one or more sensors communicatively coupled to the one or more remote devices; one or more electronic databases; one or more processors; and one or more memories, having stored thereon computer-executable instructions that, when executed by the one or more processors, cause the computing system to: receive data from the one or more remote gateway devices, wherein the data describes measurements taken by the remote sensor devices, and wherein the data describes the state of the one or more remote devices; process, via the one or more processors, the data; and cause, via the one or more processors, the processed data to be stored in the electronic database.

In a further aspect, a computer-implemented method for collecting state of health and/or state of charge of one or more vehicle batteries includes (i) receiving, from an IoT gateway device via an electronic network, physical data from at least one of a plurality of IoT battery shunt devices; (ii) processing, via at least one microcontroller unit, the physical data; and (iii) transmitting, via the electronic network, the physical data to a remote computing device.

In yet a further aspect, a non-transitory computer-readable medium includes computer-executable instructions that, when executed, cause a computer to: (i) receive, from an IoT gateway device via an electronic network, physical data from at least one of a plurality of IoT battery shunt devices; (ii) process, via at least one microcontroller unit, the physical data; and (iii) transmit, via the electronic network, the physical data to a remote computing device.

In another aspect, a computer-implemented method for monitoring state of health and/or state of charge of one or more remote devices includes (i) receiving data from one or more remote gateway devices, wherein the data describes measurements taken by one or more remote sensor devices, and wherein the data describes a state of the one or more remote devices; (ii) processing, via one or more processors, the data; and (iii) causing, via the one or more processors, the processed data to be stored in an electronic database.

In yet another aspect, a non-transitory computer-readable medium includes computer-executable instructions that, when executed, cause a computer to: (i) receive data from one or more remote gateway devices, wherein the data describes measurements taken by one or more remote sensor devices, and wherein the data describes a state of the one or more remote devices; (ii) process, via one or more processors, the data; and (iii) cause, via the one or more processors, the processed data to be stored in an electronic database.

### BRIEF DESCRIPTION OF THE FIGURES

The figures described below depict various aspects of the system and methods disclosed therein. It should be understood that each figure depicts one aspect of a particular aspect of the disclosed system and methods, and that each of the figures is intended to accord with a possible aspect thereof. Further, wherever possible, the following description refers to the reference numerals included in the following figures, in which features depicted in multiple figures are designated with consistent reference numerals.

FIG. 1 depicts an exemplary computing environment in which the techniques disclosed herein may be implemented, according to some aspects, according to some aspects.

FIG. 2A depicts an exemplary Internet of Things (IoT) battery shunt device in accordance with some aspects.

FIG. 2B depicts an exemplary circuit diagram schematic illustrative of the shunt of FIG. 2A, according to some aspects.

FIG. 2C depicts a superior surface of an exemplary PCB upon which are located a series of circuits corresponding to the circuit schematic of FIG. 2B.

FIG. 2D depicts an inferior surface of the exemplary PCB of FIG. 2C, upon which are located a series of circuits corresponding to the schematic of FIG. 2B, including a temperature sensor circuit (T1).

FIG. 2E depicts a shunt corresponding to the shunt member of FIG. 2A.

FIG. 3A depicts an exemplary an exemplary IoT battery gateway device in accordance with some aspects.

FIG. 3B depicts an exemplary circuit diagram schematic illustrative of the gateway of FIG. 3A, according to some aspects.

FIG. 3C depicts a superior surface of an exemplary PCB upon which are located a series of circuits corresponding to the schematic of FIG. 3B, according to some aspects.

FIG. 3D depicts an exemplary interface device, according to some aspects.

FIG. 4 depicts an exemplary computer-implemented method, according to some aspects.

FIG. 5 depicts an exemplary computer-implemented method, according to some aspects.

FIG. 6 depicts an exemplary computer-implemented method, according to some aspects.

The figures depict preferred aspects for purposes of illustration only. One skilled in the art will readily recognize from the following discussion that alternative aspects of the systems and methods illustrated herein may be employed without departing from the principles of the invention described herein.

### DETAILED DESCRIPTION

### Overview

The present techniques provide methods and systems for, inter alia, monitoring and managing of devices (e.g., battery devices) using a combination of custom hardware devices (e.g., internet-of-things (IoT) shunt, an IoT gateway, and/or other custom hardware), and additional computing resources (e.g., cloud computing resources that leverage machine learning techniques).

A multi-brand provider of information technology solutions to international customers in the business, government, education and healthcare industries may provide a broad array of products and services ranging from hardware and software to integrated information technology solutions such as security, cloud computing, hybrid infrastructure and digital experience. The IT solutions provider may use the present techniques to enable monitoring and management of many different types of applications.

For example, the present techniques include techniques that improve upon conventional battery monitoring and management systems by, inter alia, collecting information from batteries, transmitting the information to remote computing resources, processing the information (e.g., using one or more machine learning (ML) models to generate predictions with respect to battery status of health, status of charge, etc.; and for performing battery management/monitoring based on the generated information.

For example, the present techniques may include methods and systems for collecting information from vehicle (e.g., passenger automobile, semi-trailer, motorcycle, water vessel, autonomous vehicle, manned airplane, etc.) systems using a custom IoT device (e.g., a battery shunt) and a custom IoT gateway device (e.g., a user-serviceable or potted controller); transmitting data to remote cloud computing system (e.g., via cellular to cloud computing system); processing the information using ML/predictive analytics to identify patterns, anomalies and generate insights re. battery health/performance; causing one or more real-time monitoring via GUIs to be displayed; integrating the generated information/predictions with fleet management software (e.g., by accessing and/or providing one or more extensible application programming interfaces (APIs)); generating alerts and notifications to be transmitted/displayed; and/or by generating one or more predictive maintenance schedules. The present techniques are applicable to additional use cases/environments including but not limited to temperature/power detection (e.g., in food processing, food service, data centers, etc.).

The present techniques include an exemplary IoT-based data collection device in a motor vehicle with battery and power consumption detection functions by integrating sensors and connectivity within the vehicle. These sensors may measure battery voltage, current, and temperature, while tracking power consumption from various components. The collected data may be transmitted to a cloud analytics component, which processes and analyzes the information to provide insights on battery health, power usage patterns, and potential optimizations, enabling proactive maintenance and efficient energy management in the vehicle.

For example, an IoT device using custom electronics based on the ESP32 chipset and coded in C++ language may include an ESP32 chipset, having a microcontroller unit (MCU) that offers built-in Wi-Fi and Bluetooth capabilities, making it suitable for connecting to the internet and communicating with other devices. The chipset may combine a dual-core processor, memory, and various peripherals, providing a solid foundation for IoT applications. The IoT device may be a custom electronic component designed on a printed circuit board (PCB). The PCB design process may involves selecting and integrating various components such as sensors, actuators, power management modules, and connectors. CAD (Computer-Aided Design) software may be used for designing the PCB layout.

Depending on the embodiment, appropriate sensors and actuators may be added to the IoT device(s) to collect data or interact with the physical environment. Sensors may include temperature sensors, current sensors, voltage sensors, vehicle OBD sensors and other sensors. Circuitries may include devices such as metal-oxide-semiconductor field-effect transistors (MOSFETs), analog-to-digital converters (ADCs), and light-emitting diode (LED) displays.

LTE and 5G modules may replace the built-in Wi-Fi and Bluetooth capabilities of the ESP32 chipset. These modules may provide cellular connectivity to the IoT device, allowing it to connect to the internet and communicate with other devices via cellular networks.

The ESP32 chipset may be programmed using C++. The Arduino framework and the Espressif IoT Development Framework (ESP-IDF) may be used to develop firmware for the ESP32 in C++. These frameworks may provide libraries and APIs that simplify the development process and allow access the device's peripherals and features.

The enclosure for the present IoT device(s) may provide physical protection and aesthetics. The enclosures may be designed to fit custom electronics and accommodate any external interfaces, such as buttons, displays, or connectors. CAD software may be used to design the enclosure, and it may be manufactured using injection molding and CNC machining.

The present IoT device(s) may require a power supply and appropriate power management circuitry, such as 12v from a vehicle and voltage regulation, battery management, and power-saving techniques to optimize energy consumption. The power management system advantageously promotes efficient operation and prolonged battery life for battery-powered devices.

In addition to firmware for the ESP32 in C++, the present techniques may include developed software that may be stored and executed in one or more remote (e.g., cloud) systems This software may include server applications, web interfaces, mobile apps, or APIs that allow users to interact with and control the IoT device remotely.

Overall, the present IoT devices may be based on an ESP32 chipset and coded in C++ involves a combination of hardware design, software development, and integration of various technologies to achieve the desired functionality in a custom-manufactured enclosure. However, in some aspects, other suitable embedded chipsets and/or programming languages may be used.

### Exemplary Computing Environment

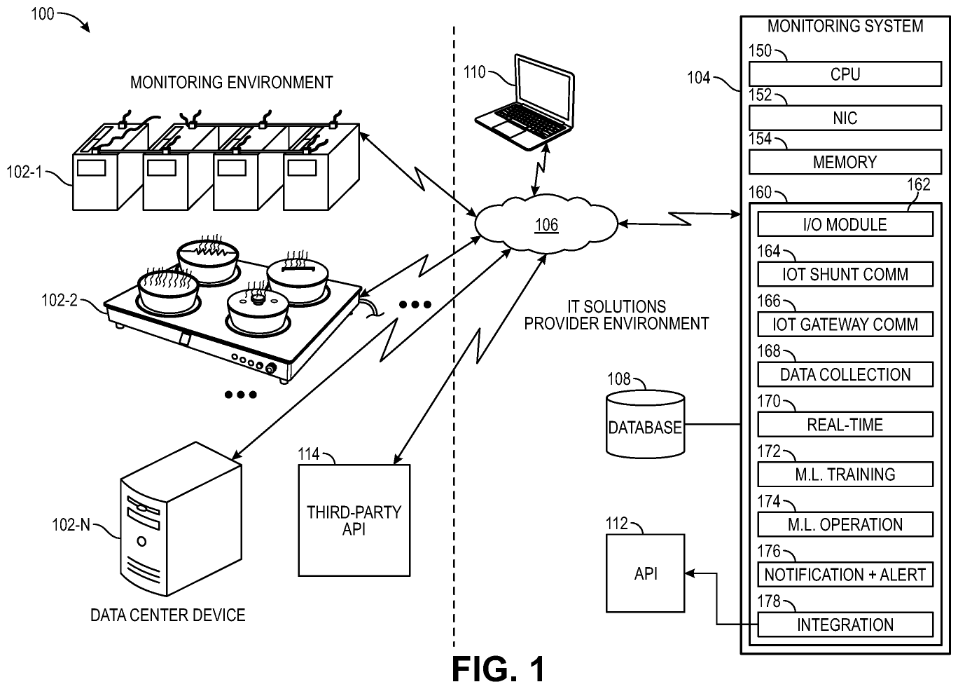

FIG. 1 depicts an exemplary computing environment 100 in which the techniques disclosed herein may be implemented, according to some aspects. The environment 100 may include one or more monitoring environments and one or more information technology (IT) provider environments. The computing environment 100 may include one or more monitored devices 102, a monitoring system 104, an electronic network 106, an electronic database 108 a client computing device 110, a local API 112 and a third-party API 114.

### Exemplary Monitored Devices

The one or more monitored devices 102 may be located within the respective one or more monitoring environments. For example, the environment 100 may include one or more battery monitored devices 102-1, one or more food service monitored devices 102-2 and one or more computing monitored devices 102-n, where n is a positive integer. That is, the environment 100 may include any number of monitored devices, distributed suitably across one or more monitoring environments. The computing monitored devices 102-1 may be batteries such as lead-acid batteries and lithium batteries (e.g., lithium phosphate, lithium ion, etc.).

In some aspects, the monitoring environment may include only one of the monitored device types (e.g., only battery devices). In some aspects, a separate/parallel computing environment 100 may be constructed that includes a different type of monitored devices (e.g., food service devices). The example of FIG. 1 is for illustrative purposes, and it should be appreciated that many alternative configurations are envisioned. For example, a separate environment may be created on a per-customer basis, on a per-device type basis, etc.

A wide array of devices, potentially of different types/configurations, may be monitored using the present techniques.

For example, the battery monitored devices 102-1 may include a single battery array or multiple-battery array. In the depicted example, the battery monitored devices 102-1 include an array of a plurality of batteries. The battery monitored devices 102-1 may be connected (e.g., in parallel, in serial, etc.). For example, the depicted battery monitored devices 102-1 may power a semi-trailer truck, which typically includes a plurality of batteries.

The one or more food service monitored devices 102-2 may include, for example, one or more pots/cauldrons of soup, as in the depicted example. The food service monitored devices 102-2 may include one or more heating or cooling elements (e.g., one or more electric coils, one or more gas-powered heating elements, one or more inductive heating elements, etc.).

The computing monitored devices 102-n may include software components, hardware components, and/or virtualized components. For example, the computing monitored devices 102-n may include bare metal computing devices, cloud computing instances/devices, microservices, etc. The computing monitored devices 102-n may each be an individual server, a group (e.g., cluster) of multiple servers, or another suitable type of computing device or system (e.g., a collection of computing resources). For example, the computing monitored devices 102-n may be any suitable computing device (e.g., a server, a mobile computing device, a smart phone, a tablet, a laptop, a wearable device, etc.). In some aspects, one or more components of the monitoring environments 102 may be embodied by one or more virtual instances (e.g., a cloud-based virtualization service). The one or more monitoring environments 102 may be included in a respective remote data center (e.g., a cloud computing environment, a public cloud, a private cloud, hybrid cloud, etc.).

The computing monitored devices 102-n may each include, respectively, a processor, a memory and a network interface controller (NIC). The processor may include any suitable number of processors and/or processor types, such as CPUs and one or more graphics processing units (GPUs). Generally, the processor is configured to execute software instructions stored in the memory. The memory may include one or more persistent memories (e.g., a hard drive/solid state memory) and stores one or more set of computer executable instructions/modules.

The computing monitored devices 102-n may each include respective input devices and respective output devices. The respective input devices may include any suitable device or devices for receiving input, such as one or more microphone, one or more camera, a hardware keyboard, a hardware mouse, a capacitive touch screen, etc. The respective output devices may include any suitable device for conveying output, such as a hardware speaker, a computer monitor, a touch screen, etc. In some cases, the input device and the output device may be integrated into a single device, such as a touch screen device that accepts user input and displays output. The tenant computing device may be associated with (e.g., owned/operated by) the IT solutions provider (e.g., a company that services enterprise customers) and may include software licensed from a third party.

The NIC of the computing monitored devices 102-n may include any suitable network interface controller(s), such as wired/wireless controllers (e.g., cellular wireless controllers, Ethernet controllers, etc.), and facilitate bidirectional/multiplexed networking over the network between the computing monitored devices 102-n and other components of the environment 100.

The one or more one or more monitored devices 102 may be communicatively coupled to one or more devices (e.g., one or more thermistors, one or more IoT shunt devices and/or one or more IoT gateway devices, etc.) (not depicted). For example, one or more of the battery monitored devices 102-1 may be coupled to a respective battery shunt (not depicted) that is in turn coupled to a gateway device. As described below, the shunt and gateway devices may collect information/data from the one or more battery monitored devices 102-A. The shunt and/or gateway devices may process, cache, store, and/or transmit the collected data to a remote computing device. In some aspects, other components (e.g., the monitored food service devices 102-2) may include other device configurations, such as a thermistor coupled to each food service device 102-2 and to a food service gateway device. The food service gateway device may be configured to transmit information from the thermistor to a remote computing device. Other combinations of data collection devices may be combined one additional gateways to provide data collection for a variety of use cases.

### Exemplary Monitoring System

The monitoring system 104 includes a processor 150, a NIC 152 and a memory 154. The monitoring system 104 may further include a database 180. The database 180 may be a structured query language (SQL) database (e.g., a MySQL database, an Oracle database, etc.) or another type of database (e.g., a not only SQL (NoSQL) database). The monitoring system 104 may include a library of client bindings for accessing the database 180. In some aspects, the database 180 is located remote from the monitoring system 104. For example, the database 180 may be implemented using a RESTdb.IO database, an Amazon Relational Database Service (RDS), etc. in some aspects. In some aspects, the monitoring system 104 may include a client-server platform technology such as Python, PHP, ASP.NET, Java J2EE, Ruby on Rails, Node.js, a web service or online API, responsive for receiving and responding to electronic requests.

The processor 150 may include any suitable number of processors and/or processor types, such as CPUs and one or more graphics processing units (GPUs). Generally, the processor 150 is configured to execute software instructions stored in the memory 154. The memory 154 may include one or more persistent memories (e.g., a hard drive/solid state memory) and stores one or more set of computer executable instructions/modules 160, including an input/output (I/O) module 162, an IoT shunt communication module 164, an IoT gateway communication module 166, a data collection module 168, a real-time monitor module 170, a machine learning training module 172, a machine learning operation module 174, a notification and alerts module 176; and an API integration module 178.

Each of the modules 160 implements specific functionality related to the present techniques, as will be described further below. In some aspects, a plurality of the modules 160 may work in concert to implement a particular technique. For example, the data collection module 168 may work with the I/O module and the IoT gateway communication module 166 to authenticate and begin receiving and/or storing data from one or more of the monitored devices 102. Thus, the modules 160 may exchange data via suitable techniques, e.g., via inter-process communication (IPC), a Representational State Transfer (REST) API, etc. within a single computing device/system, such as the monitoring system 104 (as configured in some aspects). Or, in aspects wherein the monitoring system 104 is implemented using multiple components (e.g., multiple servers), a first device may perform authentication, while another performs IoT programming and yet another receives data. That is, the module 160 may be redistributed across multiple computing devices/memories, for scaling purposes or for other purposes. The modules 160 of FIG. 1 will now be described in greater detail.

Generally, the I/O module 162 includes instructions that enable a user (e.g., an employee of the IT solutions provider) to access and operate the monitoring system 104 (e.g., via the client computing device 110). For example, the employee may be a software developer who trains one or more ML models using the ML training module 172 in preparation for using the one or more trained ML models to predict battery performance of one or more of the battery monitored devices 102-1. Once the one or more ML models are trained, the user may access the monitoring system 104 via the I/O module to test and/or deploy the trained ML model(s). The I/O module 162 may include instructions for generating one or more graphical user interfaces (GUIs) that collect and store parameters. For example, the I/O module 162 may include user interfaces that enable the user to add one or more monitored devices 102 and/or one or more monitoring environments. The user interfaces may enable the user to associate monitored devices 102 with monitoring environments, and vice versa.

The I/O module 162 may include instructions for authenticating via one or more authentication methods. The I/O module 162 may facilitate one or more remote devices (e.g., one or more IoT gateway devices associated with the monitored devices 102). For example, the I/O module may include software libraries for accessing the IT solutions provider's authentication databases/directories. The I/O module 162 may authenticate the devices via API authentication methods (e.g., via cookies, public key certificates, etc.). In some aspects (e.g., multi-factor authentication aspects) the I/O module 162 may receive one-time use passwords from a user.

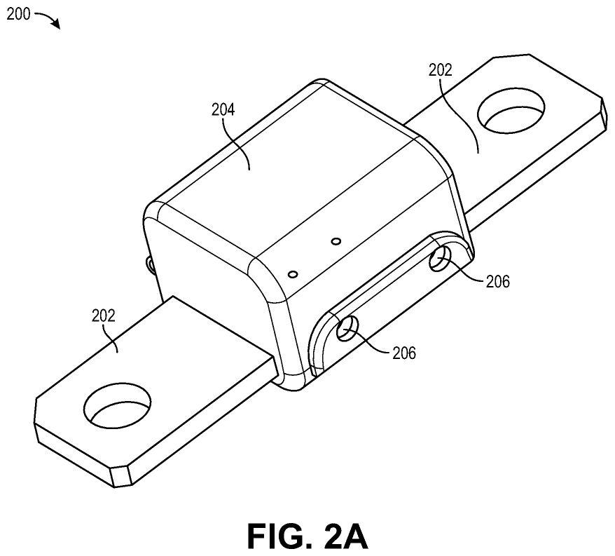

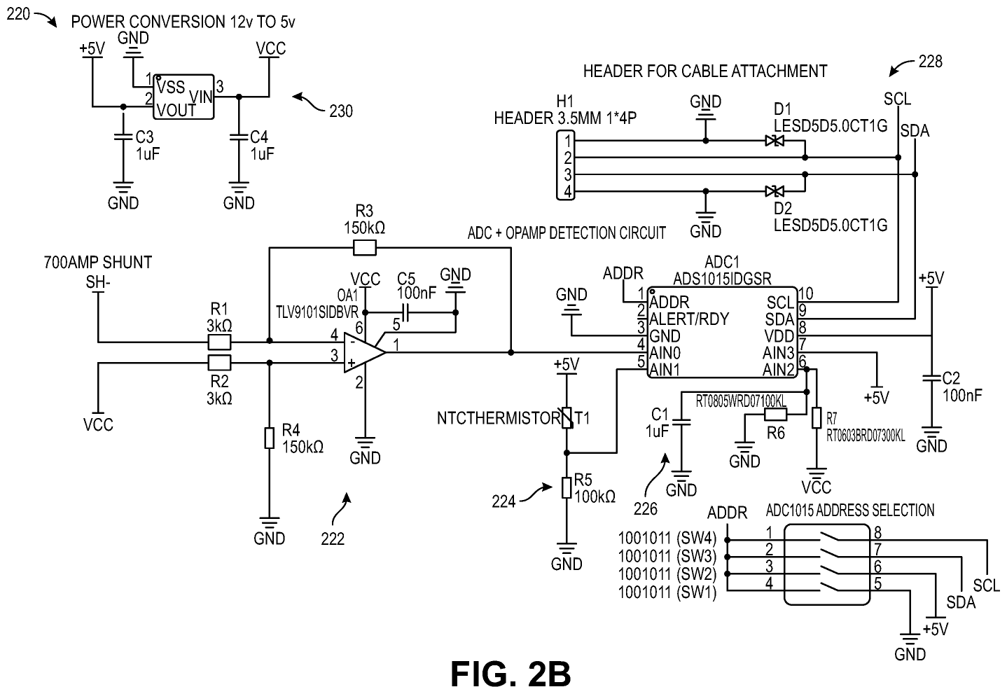

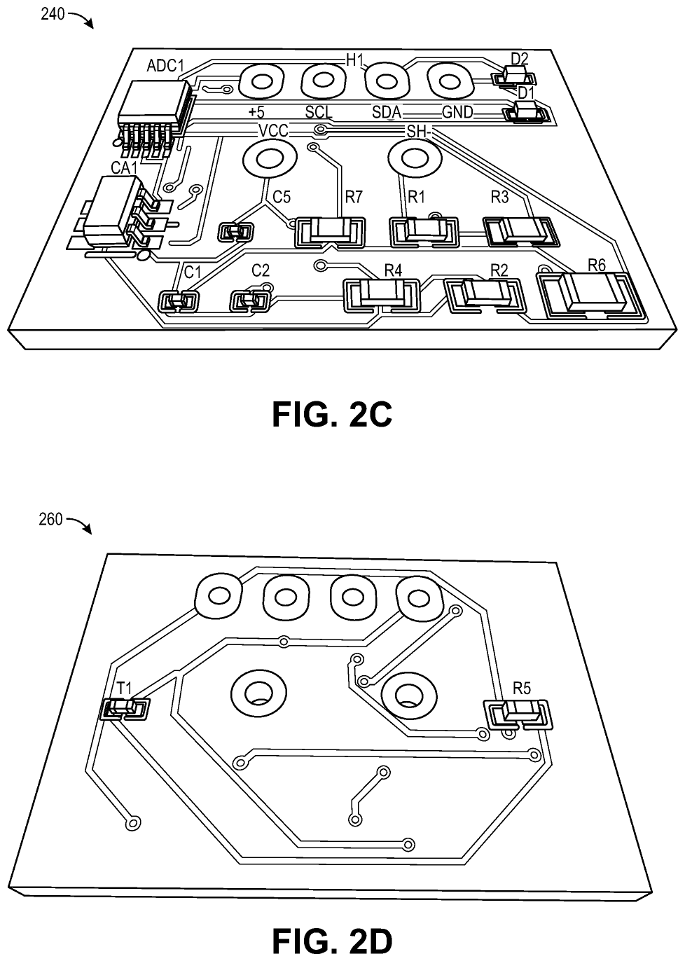

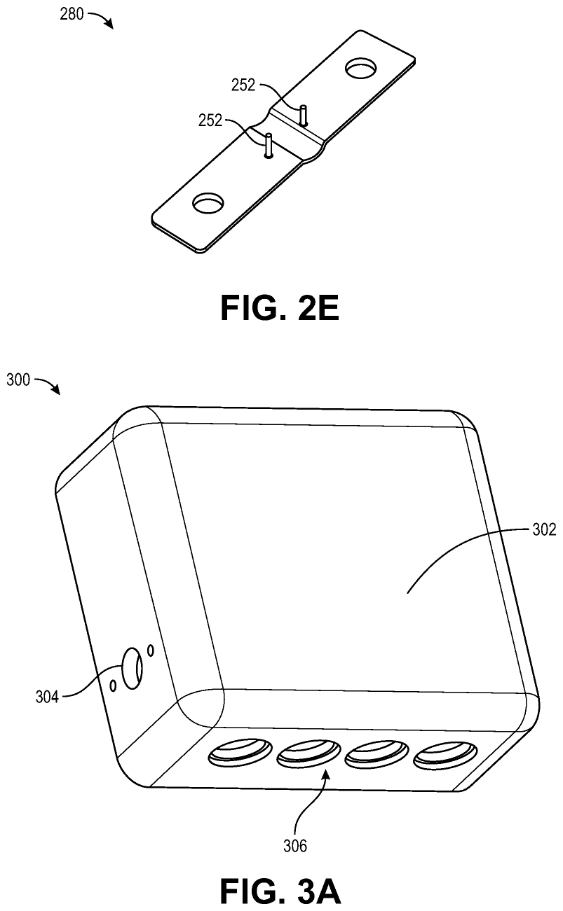

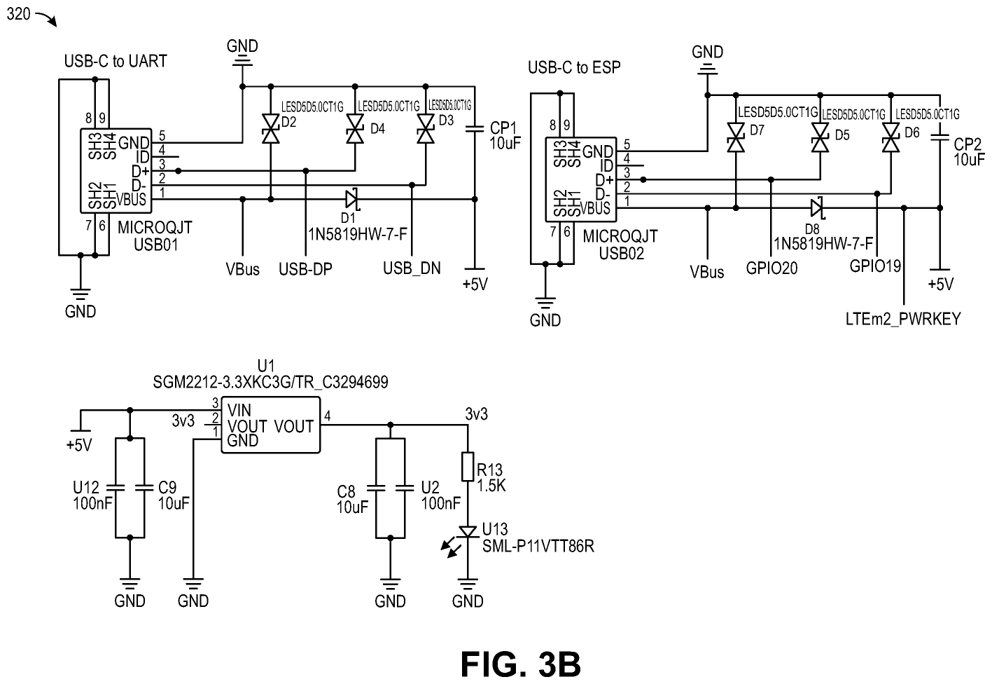

The IoT shunt communication module 164 may include one or more sets of computer-executable instructions (e.g., software libraries) for testing/calibrating one or more shunt IoT devices, such as the shunt IoT device depicted in FIG. 2A.

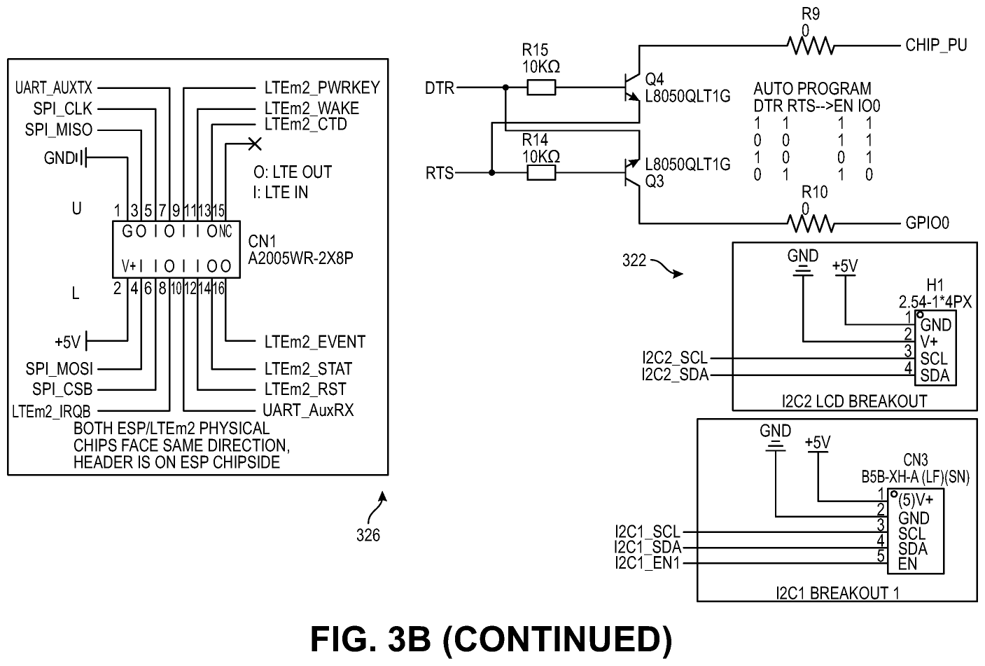

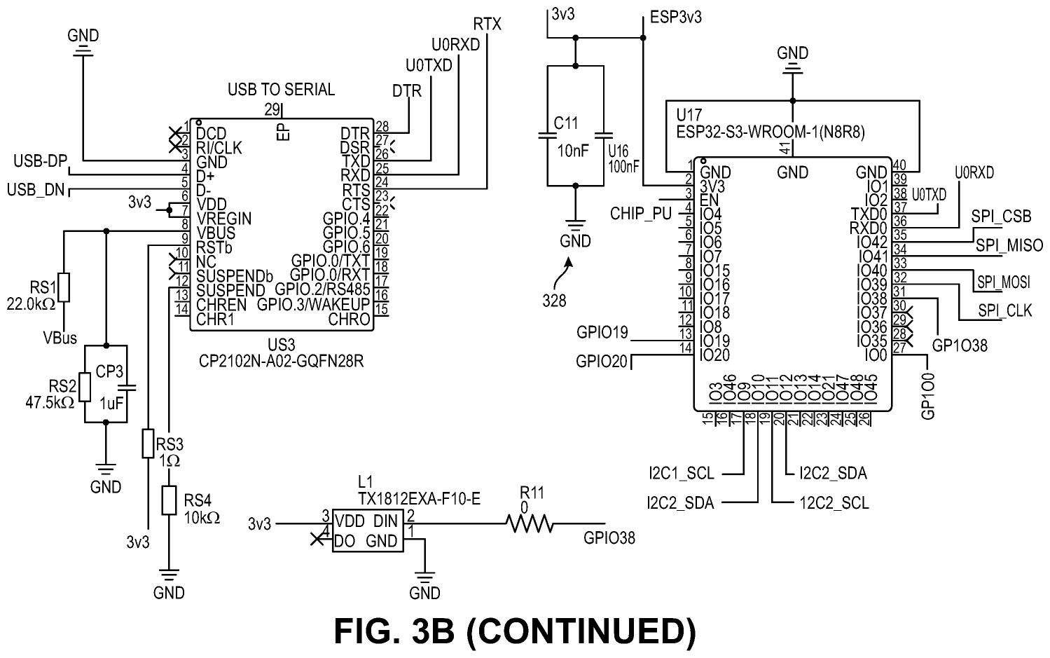

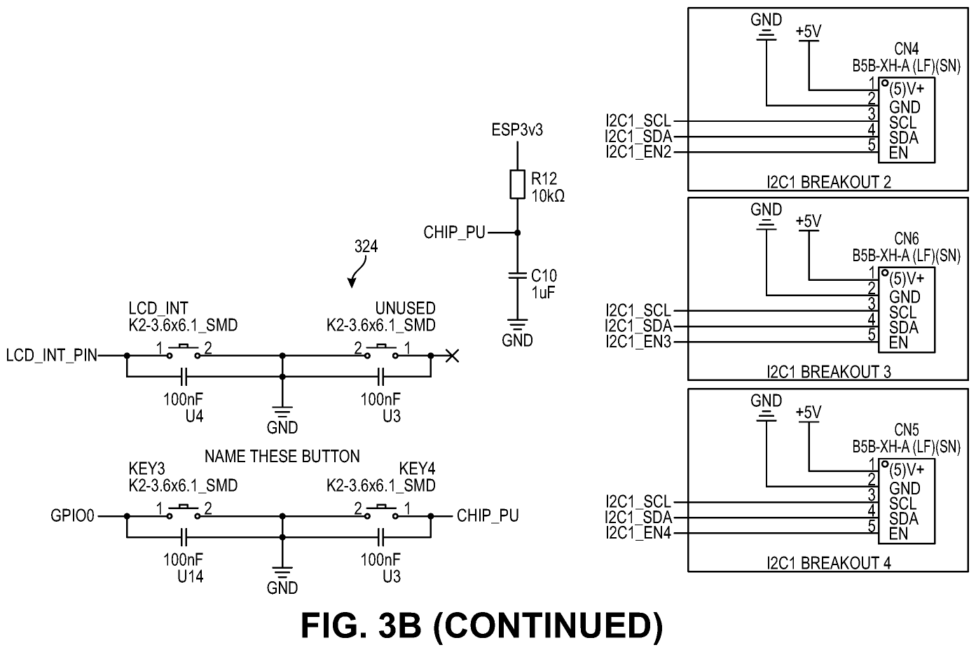

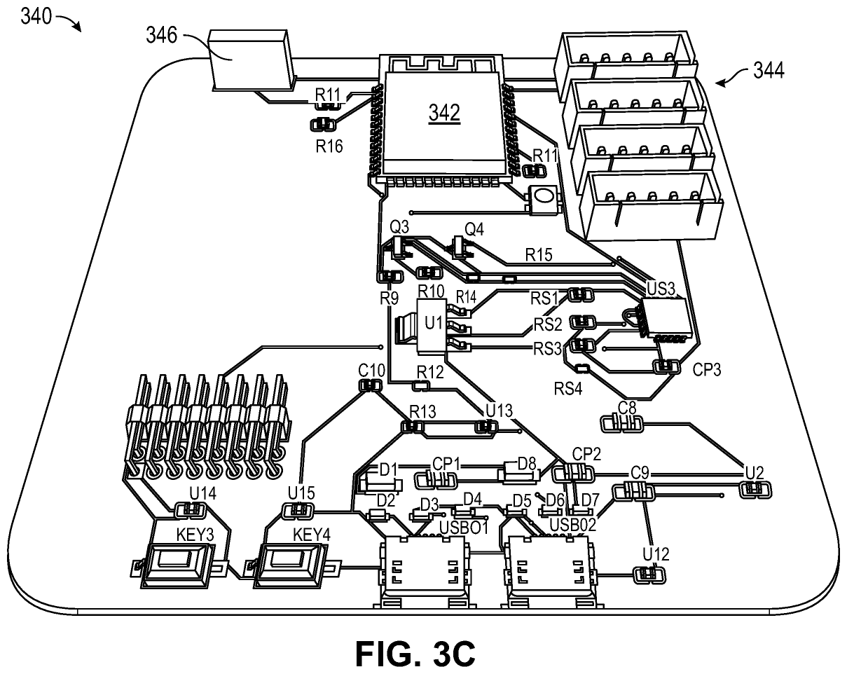

The IoT gateway communication module 166 may include one or more sets of computer-executable instructions for testing/calibrating/configuring one or more gateway IoT devices, such as the gateway IoT device depicted in FIG. 3A. Specifically, the IoT gateway module 166 may include one or more sets of computer-executable instructions for loading program instructions into a memory of the IoT gateway module 166.

The data collection module 168 may include one or more sets of computer-executable instructions for receiving/retrieving data from the monitored devices 102.

The real-time monitor module 170 may include one or more sets of computer-executable instructions for initiating real-time receipt/retrieval of data from the monitored devices 102, according to a periodic schedule or on a real-time or substantially real-time basis. For example, the real-time monitor module 170 may include an event-driven system for retrieving data from one or more of the monitored devices 102 (e.g., via one or more gateway IoT devices via the network 106). In some aspects, the monitored devices 102 may maintain one or more persistent network connections and retrieve data via those persistent connections (e.g., via polling the devices). In still further embodiments, other techniques may be used, such as messing queues, PubSub, etc.

It may not be possible to directly measure the impedance of a battery once the battery is connected (e.g., to a vehicle). This is because measuring the battery's impedance once connected will measure the impedance of the vehicle, not the battery. Further, as batteries age, they may produce more heat, and impedance may also increase. State of health and state of charge are related directly to impedance. Known current, with known voltage at load and voltage at rest can mathematically calculate impedance/resistance of battery in ohms. Such computations may be performed on a device (e.g., a microcontroller) and/or in a remote computing device. In some aspects, temperature may be omitted from the computations. The state of health and state of charge may be determined using techniques such as those described in “Development of an algorithm for estimating Lead-Acid Battery State of Charge and State of Health,” by Samolyk et al.; Blekinge Inst. Tech; September 2013, hereby incorporated by reference for all purposes. In particular, state of charge and state of health may be determined by equations modeling certain inputs (e.g., voltage at rest, voltage at load, and current in amps) to determine impedance of a battery. Such computations may be performed by the monitoring system 104.

The machine learning training module 172 may include one or more sets of computer-executable instructions for training one or more ML models. For example, the machine learning training module 172 may train one or more machine learning models using labeled historical data. For example, data representing battery state of charge and/or state of health data may be labeled according to whether the data corresponds to a battery that is failing or in good health, or in between. The machine learning module 172 may train a model to predict, based on new data that the model has not seen previously, whether a battery corresponding to the new data is failing, not failing or in between. The machine learning model may output a percentage corresponding to the impedance of the battery, in some aspects. In some aspects, public (e.g., open source) and/or proprietary (e.g., commercially-available) machine learning models may be used for the present techniques.

The ML training module 172 may train one or more ML models (e.g., an artificial neural network (ANN)). One or more training data sets may be used for model training in the present techniques, as discussed herein. The input data may have a particular shape that may affect the ANN network architecture. The elements of the training data set may comprise tensors scaled to small values (e.g., in the range of (−1.0, 1.0)). In some aspects, a preprocessing layer may be included in training (and operation) which applies principal component analysis (PCA) or another technique to the input data. PCA or another dimensionality reduction technique may be applied during training to reduce dimensionality from a high number to a relatively smaller number. Reducing dimensionality may result in a substantial reduction in computational resources (e.g., memory and CPU cycles) required to train and/or analyze the input data.

In general, training an ANN may include establishing a network architecture, or topology, adding layers including activation functions for each layer (e.g., a “leaky” rectified linear unit (ReLU), softmax, hyperbolic tangent, etc.), loss function, and optimizer. In an aspect, the ANN may use different activation functions at each layer, or as between hidden layers and the output layer. A suitable optimizer may include Adam and Nadam optimizers. In an aspect, a different neural network type may be chosen (e.g., a recurrent neural network, a deep learning neural network, etc.). Training data may be divided into training, validation, and testing data. For example, 20% of the training data set may be held back for later validation and/or testing. In that example, 80% of the training data set may be used for training. In that example, the training data set data may be shuffled before being so divided. Data input to the artificial neural network may be encoded in an N-dimensional tensor, array, matrix, and/or other suitable data structure. In some aspects, training may be performed by successive evaluation (e.g., looping) of the network, using training labeled training samples. As discussed below, training may be performed using a feedback mechanism (e.g., additional training samples) at runtime, to improve the performance of the one or more trained model over time.

The process of training the ANN may cause weights, or parameters, of the ANN to be created. The weights may be initialized to random values. The weights may be adjusted as the network is successively trained, by using one or more gradient descent algorithms, to reduce loss and to cause the values output by the network to converge to expected, or “learned”, values. In an aspect, a regression may be used which has no activation function. Therein, input data may be normalized by mean centering, and a mean squared error loss function may be used, in addition to mean absolute error, to determine the appropriate loss as well as to quantify the accuracy of the outputs. In some aspects, the present techniques may include one or more ML models that perform a regression analysis.

In various aspects, an ML model, as described herein, may be trained using a supervised or unsupervised machine learning program or algorithm. The machine learning program or algorithm may employ a neural network, which may be a convolutional neural network, a deep learning neural network, and/or a combined learning module or program that learns in two or more features or feature datasets (e.g., structured data, unstructured data, etc.) in a particular areas of interest. The machine learning programs or algorithms may also include natural language processing, semantic analysis, automatic reasoning, regression analysis, support vector machine (SVM) analysis, decision tree analysis, random forest analysis, K-Nearest neighbor analysis, naïve Bayes analysis, clustering, reinforcement learning, and/or other machine learning algorithms and/or techniques. In some aspects, the artificial intelligence and/or machine learning based algorithms may be based on, or otherwise incorporate aspects of one or more machine learning algorithms included as a library or package executed on server(s) 104. For example, libraries may include the TensorFlow based library, the Pytorch library, and/or the scikit-learn Python library.

Machine learning may involve identifying and recognizing patterns in existing data (e.g., device status data) in order to facilitate making predictions, classifications, and/or identifications for subsequent data (such as using the models to determine or generate a classification or prediction for, or associated with, the status or health of a device). Machine learning model(s), may be created and trained based upon example data (e.g., “training data”) inputs or data (which may be termed “features” and “labels”) in order to make valid and reliable predictions for new inputs, such as testing level or production level data or inputs. In supervised machine learning, a machine learning program operating on a server, computing device, or otherwise processor(s), may be provided with example inputs (e.g., “features”) and their associated, or observed, outputs (e.g., “labels”) in order for the machine learning program or algorithm to determine or discover rules, relationships, patterns, or otherwise machine learning “models” that map such inputs (e.g., “features”) to the outputs (e.g., labels), for example, by determining and/or assigning weights or other metrics to the model across its various feature categories. Such rules, relationships, or otherwise models may then be provided subsequent inputs in order for the model, executing on the server, computing device, or otherwise processor(s), to predict, based on the discovered rules, relationships, or model, an expected output. For example, the ML training module 172 may analyze labeled historical data at an input layer of a model having a networked layer architecture (e.g., an artificial neural network, a convolutional neural network, a deep neural network, etc.) to generate ML models. The training data may be, for example, historical data related to device functioning.

During training, the labeled data may be propagated through one or more connected deep layers of the ML model to establish weights of one or more nodes, or neurons, of the respective layers. Initially, the weights may be initialized to random values, and one or more suitable activation functions may be chosen for the training process. One or more ML models may be trained to predict outputs based on the training data, and the ML training module 172 may include training a respective output layer of the one or more machine learning models. The output layer may be trained to output a prediction, for example.

Once the model training module 172 has initialized the one or more ML models, which may be ANNs or regression networks, for example, the model training module 172 trains the ML models by inputting labeled data into the models.

The model training module 172 may divide the labeled data into a respective training data set and testing data set. The model training module 172 may train the ANN using the labeled data. The model training module 172 may compute accuracy/error metrics (e.g., cross entropy) using the test data and test corresponding sets of labels. The model training module 172 may serialize the trained model and store the trained model in a database (e.g., the database 108). The model training module 172 may train and store more than one model.

In some aspects, the computing modules 160 may include a machine learning operation module 174, comprising a set of computer-executable instructions implementing machine learning loading, configuration, initialization and/or operation functionality. The ML operation module 174 may include instructions for storing trained models (e.g., in the electronic database 108, as a pickled binary, etc.). Once trained, a trained ML model may be operated in inference mode, whereupon when provided with de novo input that the model has not previously been provided, the model may output one or more predictions, classifications, device health predictions, etc. as described herein.

Once the model(s) are trained by the model training module 170, the model operation module 174 may load one or more trained models (e.g., from the database 180). The model operation module 174 may apply new data that the trained model has not previously analyzed to the trained model. For example, the model operation module 174 may load a serialized model, deserialize the model, and load the model into memory. The model operation module 174 may load new device status data that was not used to train the trained model. In other aspects, only historical data may be used to generate simulated device data. The model operation module 174 may apply one or more input tensor(s) to the trained ML model. The model operation module 174 may receive output (e.g., tensors, feature maps, etc.) from the trained ML model. The machine learning operation module 174 may include one or more sets of computer-executable instructions for operating one or more ML models.

The notification and alerts module 176 may include one or more sets of computer-executable instructions for generating and/or transmitting one or more notifications and/or alerts. For example, the notifications may be sent via email, via text message/SMS, via push notification, etc. The notification and alerts module 176 may cause the alerts to be transmitted and displayed to one or more mobile devices (e.g., one or more smart phones) belonging to a vehicle driver, a store employee, a data center employee/operator/engineer, an employee of the IT solutions provider, a fleet manager/administrator, etc. The content of the notification alerts module may relate to one or more pre-determined conditions. The notification and alerts module 176 may receive the pre-determined conditions from the database 108. For example, a pre-determined condition may relate to a state of charge of a battery, a temperature of a food service item, a condition (e.g., a temperature, humidity, etc.) of a data center device, etc.

The API integration module 178 may include one or more sets of computer-executable instructions for integrating the present techniques through the use of one or more APIs. In particular, the internal API 112 may be used to provide an API by which other services/parties may consume information generated by the monitoring system. For example, the API integration module 178 may publish an API endpoint that enables a subscriber (e.g., a trucking company) to subscribe to failing batteries that are part of the battery devices 102-A. In some aspects, the monitoring system 104 may submit information via the third-party API. For example, when the monitoring system 104 determines that a particular battery in the batteries 102-1 is operating at a certain failure rate (e.g., has an impedance beyond a predetermined threshold, or an impedance that suddenly spiked) or has already failed, the monitoring system 104 (e.g., the integration module 178) may submit a POST request to the third-party API 114 with parameters identifying the battery. The integration module 178 may further include instructions that when executed cause additional events to occur. For example, in some aspects, the integration module 178 may process location of the vehicle and/or route information of the vehicle to which the failing/failed battery belongs.

The integration module 178 may include instructions that identify service stations along the route of the vehicle.

The integration module 178 may include instructions that order parts and/or labor to be made available to the vehicle at an approximate time, such that the installation of a new battery to replace the failing battery is facilitated in a manner that advantageously minimizes the downtime of the vehicle, while also maintaining high battery performance. In addition to optimizing vehicle/fleet travel, this has the added benefit of increasing efficiency of capital for battery purchasing, and reducing the amount of storage space needed to house batteries, by only ordering batteries for replacement when they are needed. For example, instead of replacing batteries every year, the fleet may only need to replace batteries every 18 months.

In some aspects, the integration module 178 may simply provide a continuous/periodic stream of information for all batteries in a fleet, including state of health and state of charge, via the API 112 or the API 114. The fleet management company may then use the provided information for their own purposes.

The network 106 may be a single communication network, or may include multiple communication networks of one or more types (e.g., one or more wired and/or wireless local area networks (LANs), and/or one or more wired and/or wireless wide area networks (WANs) such as the Internet). The network 106 may enable bidirectional communication between the monitoring environments 102 and the various components of the IT solutions provider environment, such as the monitoring system 104, the database 108, etc.

### Exemplary IoT Battery Shunt Device

As discussed above, the devices 102 in the monitoring environment of FIG. 1 may be coupled to an IoT shunt, in some aspects. FIG. 2A depicts an exemplary IoT battery shunt device 200 in accordance with some aspects. The IoT shunt device 200 may include a shunt member 202 and a housing 204. Each wing of the shunt protruding from the housing 204 may include a respective annular opening wide enough to allow an electric cable to pass through. The shunt member 202 may be composed of an electro-conductive material, and the housing 204 may be hinged to allow for a user to service the shunt device 200, in some aspects. In other aspects, the housing 204 may be permanently sealed shut (e.g., using epoxy or another sealant/bonding compound). The shunt device 200 may include electronic components, such as a printed circuit board (PCB), which may be contained within the housing 204. The shunt member 202 may include one or more ports 206 through which wires may be fed. The housing 204 may provide waterproofing capabilities, e.g., to exceed IP-68. The dimensions of the housing 204 may be approximately four inches by four inches by two inches.

Each wing of the shunt member 202 protruding from the housing 204 may include a respective annular opening wide enough to allow an electric cable to pass through. The shunt member 202 may be composed of an electro-conductive material, and the housing 204 may be hinged to allow for a user to service the shunt device 200, in some aspects. In other aspects, the housing 204 may be permanently sealed shut (e.g., using epoxy or another sealant/bonding compound). The shunt device 200 may include electronic components, such as a printed circuit board (PCB), which may be contained within the housing 204. The shunt device 200 may include one or more ports 206 through which wires may be fed.

FIG. 2B depicts an exemplary circuit diagram schematic 220 illustrative of the shunt 200, according to some aspects. The schematic 220 may be implemented in the PCB of the housing 204, for example. The schematic 220 includes a current measurement circuit 222, a battery temperature measurement circuit 224 and a rest-load voltage circuit 226.

The current measurement circuit 222 may measure current from a battery (e.g., one of the batteries of the array 102-A), e.g., in amperage. The battery temperature circuit 224 may measure temperature of the battery. The rest-load circuit 226 may measure the voltage of the battery at rest and at load.

The outputs of the current measurement circuit 222, the battery temperature measurement circuit 224 and the rest-load voltage circuit 226 may be provided, via a header 228, to another device (e.g., to a gateway IoT device). It should be noted that the schematic 220 may include other utility circuits, such as a voltage conversion circuit 230.

FIG. 2C depicts a superior surface of an exemplary PCB 240 upon which are located a series of circuits corresponding to the schematic 220.

FIG. 2D depicts an inferior surface of the exemplary PCB 240 upon which are located a series of circuits corresponding to the schematic 220, including a temperature sensor circuit (T1). The T1 thermistor is advantageously placed on the inferior side of the PCB 240, because the PCB 240 is placed on top of the shunt 200, and the temperature of the shunt is the subject of the measurement of the thermistor T1.

Both of FIGS. 2C and 2D include a pair of annular openings in the PCB into which terminals of a shunt may be inserted, such as the shunt depicted in FIG. 2E. FIG. 2E depicts a shunt 250 corresponding to the shunt member 202 of FIG. 2A. The shunt 250 includes two posts 252 and may be composed of a piece of conductive material (e.g., steel). The shunt 250 may be imposed between a battery and its cable, such as between each batter 102-1 and its cable of FIG. 1. The annular openings of the PCB 240 may line up precisely with the posts 252, such that each post and the center of each corresponding annular opening is disposed approximately 7 mm apart. This enables the shunt 250 to fit neatly into the PCB 240, and for the PCB 240 to read the electrical values passing through the shunt 250. The shunt 250 also acts as a structural base for the combined shunt member 202 and housing 204 of FIG. 2A. The resistance of the shunt 250 is known, such that the voltage difference between the pins is known, and load can be determined on that basis.

### Exemplary IoT Battery Gateway Device

FIG. 3A depicts an exemplary an exemplary IoT battery gateway device 300 in accordance with some aspects. The IoT battery gateway device 300 may include a housing 302 having an annular opening 304 into which electric power wires (e.g., A/C or D/C) may be fed. A perpendicular surface of the housing may include one or more annular openings 306 into which wires from one or more IoT battery shunt devices (e.g., one or more of the IoT battery shunt device 200) may be fed. Thus, the IoT gateway device 300 may receive information from the one or more IoT battery shunt devices.

FIG. 3B depicts an exemplary circuit diagram schematic 320 illustrative of the gateway 300, according to some aspects. The schematic 320 may be implemented in the PCB of the housing 302, for example. The schematic 320 includes one or more battery port circuits 322. While the schematic depicts four battery port circuits 322, in some aspects, fewer (e.g., one) or more (e.g., ten or more) battery ports may be included in the schematic 320. One or more LCD circuits 324 may be included, in some aspects. One or more cellular modem circuits 326 may be included, in some aspects. Finally, one or more microcontroller circuits 328 may be included, that are capable of reading data from/writing data to the interface circuits 322, the LCD circuits 324 and the modem circuits 326. The microcontroller 328 may include an SPI bus, an I2C bus, GPIO pins, and power supply modules, including capacitors that ensure stable and noise-free operation of the microcontroller, especially in the presence of voltage fluctuation. The circuit diagram schematic 320 includes additional components related to voltage regulation, USB communication, and powering up/resetting chips.

FIG. 3C depicts a superior surface of an exemplary PCB 340 upon which are located a series of circuits corresponding to the schematic 220. The PCB 340 may include a microcontroller 342. The microcontroller 342 may include Wi-Fi and/or Bluetooth capabilities, such as, for example, an ESP32 microcontroller. The microcontroller 342 may include multi-core processors, memory and various peripheral controllers. FIG. 3C depicts battery ports 344 into which the shunts are plugged. FIG. 3C depicts an LED/LCD interface 346, modem interface and USB interfaces. The PCB 340 may be included in the housing 302. The microcontroller 342 may access one or more sensors that are part of the IoT battery gateway device 300 (and/or another gateway device 300) and/or the shunt 200 (and/or another sensor device).

The microcontroller 342 may specifically execute one or more library software routines (e.g., C++ code, C code, assembly code, etc.) stored in a non-volatile or volatile memory of the PCB 340. The library software routines may include computer-executable instructions for reading, processing and/or transmitting data to a remote computing device (e.g., a cloud computing environment such as InfluxDB), for example via the cellular modem of the PCB 340. In some aspects, the data may be cached in memory (e.g., when the cellular modem connection is not available, such as when a vehicle in which the PCB 340 is located is in an area without network coverage, or with degraded coverage). Thus, the microcontroller 342 may access computer-executable instructions that buffer information retrieved from one or more sensors in the memory of the PCB 340. As noted, in some aspects, PubSub may be used to transmit data to/from the one or more IoT gateway devices (e.g., Message Queue Telemetry Transport (MQTT)).

FIG. 3D depicts an exemplary interface device 360. The depicted interface device 360 may be an off-the-shelf interface that is connectable to a vehicle's onboard diagnostics (OBD) port that enables the gateway with Bluetooth capabilities. Another type of device may be used, in some aspects, such as a Wi-Fi device. The device may provide all vehicle telemetry to the gateway, including CANBUS, RS45 and ISO-based information. The gateway may receive the information and transmit it to the monitoring system 104, which may in turn store the data in the database 108 (e.g., in a data lake).

Generally, the IoT shunt device and/or IoT gateway device (collectively “IoT devices” may be installed within the vehicle, typically near the battery or within the engine compartment. The IoT devices may connect to the battery terminals and the vehicle's electrical system to gather the necessary data.

Once installed, the IoT devices may continuously collect data from various sensors embedded within the vehicle. These sensors may monitor essential battery parameters such as voltage, current, temperature, and state of charge. The IoT devices may also gather information from other vehicle systems, such as the charging system or energy consumption (e.g., via OBD).

The IoT devices (or one such device, such as the IoT gateway device 300 of FIG. 3A) may utilize data connectivity, such as cellular, to establish a connection with the cloud (e.g., via the network 106). The IoT devices (or one device) may transmit the collected battery data in real-time to a cloud-based platform (e.g., the monitoring system 104) for analysis and storage. This transmission may occur through an LTE or 5G, depending on the device's location. In some aspects, a docked Wi-Fi transmission technique may be used instead of, or in addition to, cellular.

The cloud-based platform (e.g., the monitoring system 104 of FIG. 1) may receive the battery data from the IoT device and apply advanced analytics techniques. Machine learning algorithms and predictive analytics models would process the data, analyzing patterns, identifying anomalies, and generating insights about the battery's health and performance (e.g., via the ML training module 172 and/or the ML operations module 176).

Specifically, the machine learning training module 172 may leverage the power of predictive analytics to anticipate potential battery failures or degradation. By analyzing historical data and identifying patterns, it could provide recommendations for preventive maintenance activities. For instance, it might suggest battery replacements or inform users about the ideal time for recharging to extend battery life.

Users, such as vehicle owners or fleet managers, may be provided with access to a user-friendly interface through a mobile application, web portal, or dedicated software (e.g., accessible via the client computing device 110). They could view real-time battery data, including voltage, state of charge, temperature, and other relevant metrics. This enables them to monitor the battery's condition and performance remotely. Specifically, the interfaces may be provided to users via the I/O module 162 and/or the integration module 178 of FIG. 1.

The IoT device and cloud-based platform may be configured to generate alerts and notifications based on predefined thresholds or abnormal battery behavior. For example, such predefined thresholds may be loaded from the database 108 by the notification and alerts module 176 of FIG. 1. For example, if the battery voltage drops below a certain level or the temperature exceeds a safe range, the monitoring system 104 may send an alert to the user's device (e.g., the device 110). These notifications may enable prompt action to be taken to prevent battery-related issues. As discussed, other actions may be taken, such as automated ordering of replacement batteries. Automated battery replacement batteries may include driver incentives, such as local gift cards.

The IoT devices may integrate with the vehicle's existing systems, such as fleet management systems or onboard diagnostics, to exchange data and enhance overall vehicle management. Advantageously, this integration allows for a holistic approach to battery monitoring and enables coordinated maintenance and optimization efforts across the entire vehicle fleet.

Overall, the IoT devices may continuously collect battery data, transmit it to the cloud for analysis, provide real-time monitoring and alerts, enable predictive maintenance recommendations, and seamlessly integrate with the vehicle's systems. By offering comprehensive insights into the battery's condition and performance, the present techniques advantageously empower users to make informed decisions, optimize battery usage, and ensure reliable and efficient vehicle operation.

The present techniques represent an improvement to the state of the art, including several unique features and advantages to the industry. The IoT devices revolutionize the way batteries are managed and monitored, providing real-time insights, and enhancing overall vehicle performance and battery life. In particular, the IoT devices are specifically designed to monitor and assess batteries in vehicles comprehensively. They employ advanced sensors and algorithms to continuously measure vital parameters such as voltage, current, temperature, and state of charge of the battery. This level of detailed monitoring goes beyond standard battery management systems commonly found in vehicles.

Further, the IoT devices leverage data connectivity to establish a seamless connection to the cloud. The IoT devices may transmit the collected battery data in real-time, enabling immediate analysis and actionable insights. This connectivity enables constant monitoring and assessment, providing a continuous stream of information about the battery's health and performance.

Still further, the IoT devices utilize cloud-based analytics to process the incoming battery data. This includes employing machine learning algorithms and predictive analytics to identify patterns, detect anomalies, and generate actionable recommendations. By harnessing the power of the cloud, the device can provide accurate and reliable insights into the battery's condition, ensuring optimal performance and longevity.

Furthermore, the IoT devices allow remote monitoring of the battery's status through a user-friendly interface accessible via smartphones, tablets, or computers. Users can view real-time data, receive alerts for critical battery conditions (e.g., low state of charge, high temperature), and access historical performance data. This feature enables proactive battery management, minimizing the risk of unexpected failures and reducing downtime.

Moreover, by leveraging the collected data and advanced analytics, the IoT devices can predict battery failures or performance degradation before they occur. Advantageously, the IoT devices enable identification of early signs of battery deterioration, such as declining capacity or increasing internal resistance, allowing vehicle owners or fleet managers to take preventive measures and plan maintenance activities proactively. This predictive maintenance approach saves time, money, and ensures optimal battery performance.

Even further, the IoTs device can seamlessly integrate with existing fleet management systems. This integration allows fleet managers to monitor and assess the battery health of multiple vehicles simultaneously, enabling efficient management of large vehicle fleets. It provides a centralized platform to monitor battery-related metrics, track performance trends, and plan battery replacements or recharging schedules effectively.

Even further still, the IoT devices are designed to be customizable and scalable according to the specific needs of different vehicles and fleet sizes. They can adapt to a wide range of battery types, including lead-acid, lithium-ion, or other emerging battery technologies. This flexibility ensures compatibility with various vehicle models and applications, making it an attractive solution for diverse industry sectors.

In summary, the IoT device for monitoring and assessing batteries in vehicles with cloud connectivity offers comprehensive battery monitoring, real-time data connectivity, cloud-based analytics, remote monitoring and alerts, predictive maintenance capabilities, integration with fleet management systems, and customizability. These unique features make it a novel and cutting-edge solution, providing significant benefits to the automotive industry and addressing critical battery management challenges.

### Exemplary Computer-Implemented Methods

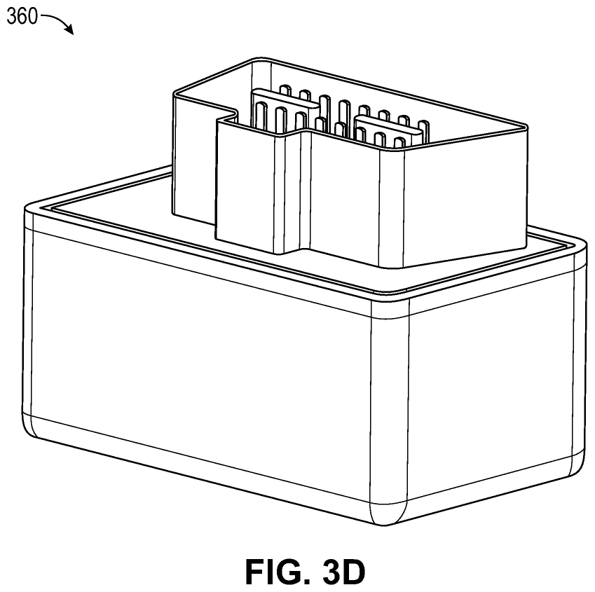

FIG. 4 depicts an exemplary computer-implemented method 400, according to some aspects. FIG. 4 may be performed by the IoT gateway device of FIG. 3A, in some aspects.

The method 400 may include a main branch 402, including importing one or more software libraries (block 404). The method 400 may include setting up one or more interfaces (e.g., I2C and/or SPI interfaces, such as those depicted in the microcontroller circuit 328 of FIG. 3B) (block 406). The method 400 may include a connecting LTE background operation (block 408).

The block 408 of the method 400 may be implemented as sub-routine that includes importing one or more libraries (block 410); connecting to a modem interface via an SPI interface (e.g., as depicted in cellular modem circuit 326) of FIG. 3B (block 412); connecting to a private network via LTE/5G (block 414); connecting an MQTT protocol to a local computing device and/or a remote computing device (e.g., the IoT gateway 300 and the monitoring system 104, respectively); determining whether the remote computing device is reachable (block 418); and/or when the device is not reachable, looping back to block 414 to attempt reconnection and when the device is reachable, continuing the sub-routine 408 (block 420).

The method 400 may include connecting to a Bluetooth onboard diagnostics (OBD) device (block 422). The block 422 of the method 400 may be implemented as a sub-routine that imports one or more libraries (block 424); connects to the OBD device via a Bluetooth interface (block 426); publishes OBD data to one or more registers of a microcontroller (block 428); determines whether the data was read (block 430); when the data was not read, loops back to publish the data to the register; and/or when the data was read, returns to read more data from a sensor (block 432).

The method 400 may further include defining a cranking function (block 434). The block 434 may be implemented as a sub-routine that includes detecting that the engine is being cranked; importing one or more libraries (block 436); setting up one or more GPIO input (block 438); determining whether the engine is being cranked (block 440); when the engine is being cranked, sampling at a number of samples per second (e.g., 1000 or more) from a sensor, and looping back to determine whether the engine is being cranked; and when the engine is not being cranked, returning to the main branch 402 of the method 400 (block 444).

The method 400 may include sampling the sensor at an interval of one minute or less (block 446). The method 400 may include monitoring the starter while the cranking function is run (block 448). The method 400 may include looping back to the sampling at block 446 (block 450).

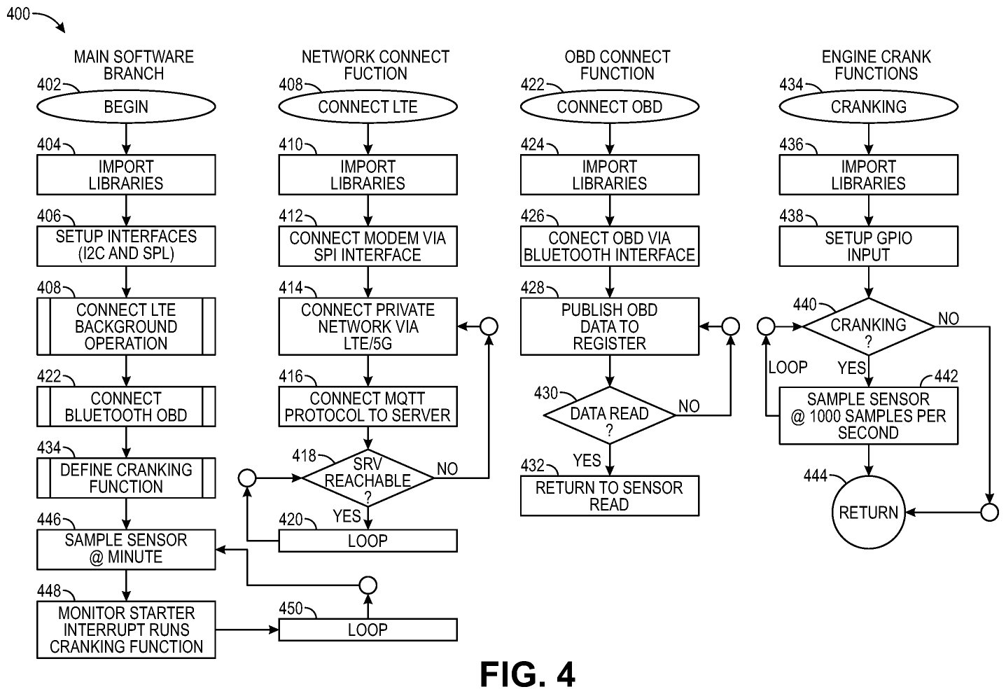

FIG. 5 depicts an exemplary computer-implemented method 500, according to some aspects. FIG. 5 may be performed by the monitoring system 104 of FIG. 1, in some aspects.

The method 500 may include receiving data from the one or more remote gateway devices, the data describing measurements taken by the remote sensor devices, and the data describing the state of the one or more remote devices (block 502). In some aspects, the one or more sensors are IoT battery shunt devices, and the one or more remote devices are vehicle batteries. In some aspects, the one or more sensors are IoT food service temperature devices, and the one or more remote devices are food service cauldrons. In some aspects, the one or more sensors are IoT temperature and/or IoT humidity, and the one or more remote devices are data center devices.

The method 500 may include processing, via the one or more processors, the data (block 504).

The method 500 may include causing, via the one or more processors, the processed data to be stored in the electronic database (block 506).

The method 500 may include receiving and/or processing the data in real-time or substantially real-time; or receiving and/or processing the data periodically and/or according to a pre-determined schedule.

In some aspects, the method 500 may include training one or more machine learning models and processing the data using one or more trained machine learning models.

The method 500 may include generating one or more notifications and/or one or more alerts.

The method 500 may include determining a route of a vehicle corresponding to the one or more vehicle batteries; and causing one or more replacement batteries to be physically shipped to a service location on the route of the one or more vehicle batteries. In some aspects, the method 500 may include ordering parts (e.g., a new heating element for a failing food service heating element). In some aspects, the method 500 may include causing an HVAC system to cool a data center region, or ordering a new part (e.g., a heatsink and thermal paste) for a data center device.

The method 500 may include submitting one or more request via an application programming interface (API), the request including at least (i) an indication of state of health of the one or more vehicle batteries and (ii) an indication of state of charge of the one or more vehicle batteries.

The method 500 may include transmitting, via the electronic network, the physical data to a remote computing device. The electronic network may be a cellular network. The physical data of at least one of the IoT battery shunt devices may include at least voltage physical data, current physical data and temperature physical data. The voltage physical data includes voltage at rest and voltage under load.

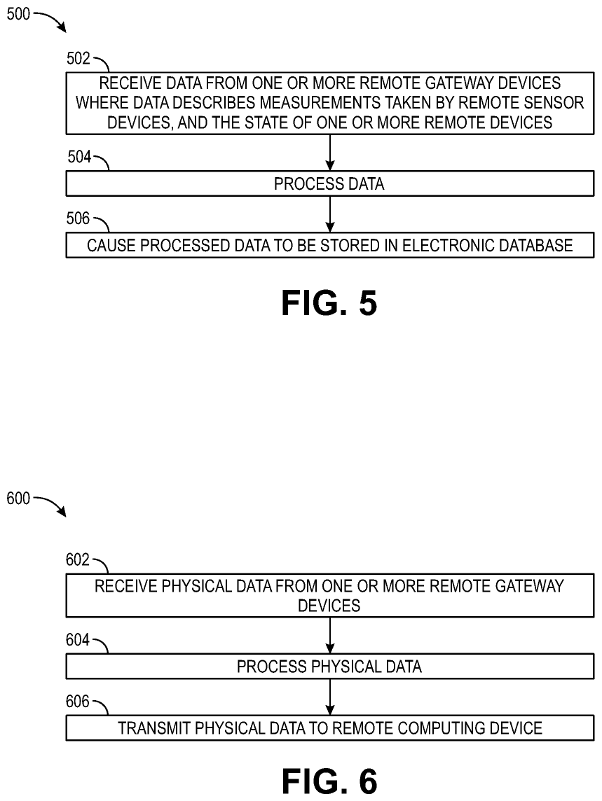

FIG. 6 depicts an exemplary computer-implemented method 600, according to some aspects. The method 600 may be performed by the gateway device 300 of FIG. 3A, in some aspects.

The method 600 may include receiving, in an IoT gateway device via an electronic network, physical data from at least one of a plurality of IoT battery shunt devices (block 602). The method 600 may include processing, via at least one microcontroller unit, the physical data (block 604). The method 600 may include transmitting, via the electronic network, the physical data to a remote computing device (block 606). For example, the remote computing device may be the monitoring system 104 of FIG. 1. The electronic network may be a cellular network. The physical data of at least one of the Internet-of-Things battery shunt devices may include at least voltage physical data, current physical data and temperature physical data. The voltage physical data includes voltage at rest and voltage under load.

Of course, the applications and benefits of the systems, methods and techniques described herein are not limited to only the above examples. Many other applications and benefits are possible by using the systems, methods and techniques described herein.

Furthermore, when implemented, any of the methods and techniques described herein or portions thereof may be performed by executing software stored in one or more non-transitory, tangible, computer readable storage media or memories such as magnetic disks, laser disks, optical discs, semiconductor memories, biological memories, other memory devices, or other storage media, in a RAM or ROM of a computer or processor, etc.

Moreover, although the foregoing text sets forth a detailed description of numerous different embodiments, it should be understood that the scope of the patent is defined by the words of the claims set forth at the end of this patent. The detailed description is to be construed as exemplary only and does not describe every possible embodiment because describing every possible embodiment would be impractical, if not impossible. Numerous alternative embodiments could be implemented, using either current technology or technology developed after the filing date of this patent, which would still fall within the scope of the claims. By way of example, and not limitation, the disclosure herein contemplates at least the following aspects:

1. An Internet-of-Things battery shunt device, comprising: a shunt member and an outer housing, the shunt member having two protruding wings each having respective annular opening through which battery wires may be passed, and the outer housing comprising: a circuit board comprising: an analog-to-digital converter circuit for converting an analog signal to a current measured in amperage; a thermal resistor circuit for measuring a temperature; an analog-to-digital converter circuit for measuring a voltage at rest and a voltage at load; and a header for transmitting the current, the temperature and the voltage.

2. The Internet-of-Things battery shunt device of aspect 1, further comprising: a 12-volt to 5-volt power conversion circuit.

3. An Internet-of-Things gateway device, comprising: a circuit board comprising: one or more microcontroller units; one or more inter-integrated circuit interfaces for receiving information; and a memory having stored thereon instructions that, when executed by the one or more microcontroller units, cause the Internet-of-Things gateway device to: receive, via the one or more microcontroller units, at least one set of one or more electro-physical measurements from at least one sensor via at least one of the inter-integrated circuit interfaces; process the electro-physical measurements; and transmit the electro-physical measurements to a remote computing device via an electronic network.

4. The Internet-of-Things gateway device of aspect 3, wherein the electro-physical measurements include at least voltage and current.

5. The Internet-of-Things gateway device of any one of aspects 3-4, wherein the electro-physical measurements further include at least temperature.

6. The Internet-of-Things gateway device of any one of aspects 3-5, the memory having stored thereon instructions that, when executed by the one or more microcontroller units, cause the IoT gateway device to: in response to determining that the remote computing device is not reachable via the electronic network, cache the electro-physical measurements in the memory for transmission at a later time.

7. The Internet-of-Things gateway device of any one of aspects 3-6, the memory having stored thereon instructions that, when executed by the one or more microcontroller units, cause the IoT gateway device to: transmit the electro-physical measurements via MQTT.

8. The Internet-of-Things gateway device of any one of aspects 3-7, wherein at least one of the microcontroller units includes one or both of (i) a Wi-Fi controller, and (ii) a Bluetooth controller.

9. The Internet-of-Things gateway device of any one of aspects 3-8, wherein the at least one of the microcontroller units is an ESP32 microcontroller unit.

10. The Internet-of-Things gateway device of any one of aspects 3-9, wherein the microcontroller units, inter-integrated circuit interfaces, and memory are stored in a pressure-tested waterproof housing.

11. A computing system for collecting state of health and/or state of charge of one or more vehicle batteries, comprising: a remote computing device; an electronic network; an Internet-of-Things gateway device comprising at least one microcontroller unit and one or more memories; and one or more Internet-of-Things battery shunt devices, wherein each Internet-of-Things battery shunt device is communicatively coupled to the Internet-of-Things gateway device via a respective annular opening in a housing of the Internet-of-Things gateway device, and wherein each Internet-of-Things battery shunt device is communicatively coupled to a respective one of the vehicle batteries; wherein the one or more memories of the Internet-of-Things gateway device include computer-executable instructions that, when executed by the at least one microcontroller unit of the Internet-of-Things gateway device, cause the Internet-of-Things gateway device to: receive, from the Internet-of-Things gateway device via the electronic network, physical data from at least one of the Internet-of-Things battery shunt devices; process, via the at least one microcontroller unit, the physical data; and transmit, via the electronic network, the physical data to the remote computing device.

12. The computing system of aspect 11, wherein the electronic network is a cellular network.

13. The computing system of any one of aspects 11-12, wherein the physical data of at least one of the Internet-of-Things battery shunt devices includes at least voltage physical data, current physical data and temperature physical data.

14. The computing system of aspect 13, wherein the voltage physical data includes voltage at rest and voltage under load.

15. A computer-implemented method for collecting state of health and/or state of charge of one or more vehicle batteries, comprising: receiving, in an Internet-of-Things gateway device via an electronic network, physical data from at least one of a plurality of Internet-of-Things battery shunt devices; processing, via at least one microcontroller unit, the physical data; and transmitting, via the electronic network, the physical data to a remote computing device.

16. The computer-implemented method of aspect 15, wherein the electronic network is a cellular network.

17. The computer-implemented method of any one of aspects 15-16, wherein the physical data of at least one of the Internet-of-Things battery shunt devices includes at least voltage physical data, current physical data and temperature physical data.

18. The computer-implemented method of aspect 17, wherein the voltage physical data includes voltage at rest and voltage under load.

19. A non-transitory computer-readable medium having stored thereon computer-executable instructions that, when executed, cause a computer to: receive, from an Internet-of-Things gateway device via an electronic network, physical data from at least one of a plurality of Internet-of-Things battery shunt devices; process, via at least one microcontroller unit, the physical data; and transmit, via the electronic network, the physical data to a remote computing device.

20. The non-transitory computer-readable medium of aspect 19, wherein the electronic network is a cellular network.

21. The non-transitory computer-readable medium of any one of aspects 19-20, wherein the physical data of at least one of the Internet-of-Things battery shunt devices includes at least voltage physical data, current physical data and temperature physical data.

22. The non-transitory computer-readable medium of aspect 21, wherein the voltage physical data includes voltage at rest and voltage under load.

23. A computing system for monitoring state of health and/or state of charge of one or more remote devices, comprising: one or more remote gateway devices configured to read sensor data from one or more sensors communicatively coupled to the one or more remote devices; one or more electronic databases; one or more processors; and one or more memories, having stored thereon computer-executable instructions that, when executed by the one or more processors, cause the computing system to: receive data from the one or more remote gateway devices, wherein the data describes measurements taken by the remote sensor devices, and wherein the data describes a state of the one or more remote devices; process, via the one or more processors, the data; and cause, via the one or more processors, the processed data to be stored in the electronic database.

24. The computing system of aspect 23, wherein the one or more sensors are Internet-of-Things battery shunt devices, and wherein the one or more remote devices are one or more vehicle batteries.

25. The computing system of any one of aspects 23-24, the one or more memories having stored thereon computer-executable instructions that, when executed by the one or more processors, cause the computing system to: determine a route of a vehicle corresponding to the one or more vehicle batteries; and cause one or more replacement vehicle batteries to be physically shipped to a service location on the route of the vehicle.

26. The computing system of any one of aspects 23-25, the one or more memories having stored thereon computer-executable instructions that, when executed by the one or more processors, cause the computing system to: submit one or more request via an application programming interface (API), the request including at least (i) an indication of state of health of the one or more vehicle batteries and (ii) an indication of state of charge of the one or more vehicle batteries.

27. The computing system of any one of aspects 23-26, wherein the one or more sensors are Internet-of-Things food service temperature devices, and wherein the one or more remote devices are food service cauldrons.

28. The computing system of any one of aspects 23-26, wherein the one or more sensors are Internet-of-Things temperature sensors and/or Internet-of-Things humidity sensors, and wherein the one or more remote devices are data center devices.

29. The computing system of any one of aspects 23-28, the one or more memories having stored thereon computer-executable instructions that, when executed by the one or more processors, cause the computing system to: receive and/or process the data in real-time or substantially real-time; or receive and/or process the data periodically and/or according to a pre-determined schedule.

30. The computing system of any one of aspects 23-29, the one or more memories having stored thereon computer-executable instructions that, when executed by the one or more processors, cause the computing system to: train one or more machine learning models by processing historical battery performance data; and process the data using one or more trained machine learning models to predict a critical battery condition.

31. The computing system of any one of aspects 23-30, the one or more memories having stored thereon computer-executable instructions that, when executed by the one or more processors, cause the computing system to: generate one or more notifications and/or one or more alerts.

32. A computer-implemented method for monitoring state of health and/or state of charge of one or more remote devices, comprising: receiving data from one or more remote gateway devices, wherein the data describes measurements taken by one or more remote sensor devices, and wherein the data describes a state of the one or more remote devices; processing, via one or more processors, the data; and causing, via the one or more processors, the processed data to be stored in an electronic database.

33. The computer-implemented method of aspect 32, wherein the one or more sensors are Internet-of-Things battery shunt devices, and wherein the one or more remote devices are one or more vehicle batteries.

34. The computer-implemented method of any one of aspects 32-33, further comprising: determining a route of a vehicle corresponding to the one or more vehicle batteries; and causing one or more replacement vehicle batteries to be physically shipped to a service location on the route of the vehicle.

35. The computer-implemented method of aspects 33-34, further comprising submitting one or more request via an application programming interface (API), the request including at least (i) an indication of state of health of the one or more vehicle batteries and (ii) an indication of state of charge of the one or more vehicle batteries.

36. The computer-implemented method of aspect 32, wherein the one or more sensors are Internet-of-Things food service temperature devices, and wherein the one or more remote devices are food service cauldrons.

37. The computer-implemented method of aspect 32, wherein the one or more sensors are Internet-of-Things temperature sensors and/or Internet-of-Things humidity sensors, and wherein the one or more remote devices are data center devices.

38. The computer-implemented method of any one of aspects 32 and 37 further comprising: receiving and/or processing the data in real-time or substantially real-time; or receiving and/or processing the data periodically and/or according to a pre-determined schedule.

39. The computer-implemented method of any one of aspects 32 and 37-39, further comprising: training one or more machine learning models by processing historical battery performance data; and processing the data using one or more trained machine learning models to predict a critical battery condition.

40. The computer-implemented method of any one of aspects 32-39, further comprising: generating one or more notifications and/or one or more alerts.

41. A non-transitory computer-readable medium having stored thereon computer-executable instructions that, when executed, cause a computer to: receive data from one or more remote gateway devices, wherein the data describes measurements taken by one or more remote sensor devices, and wherein the data describes a state of the one or more remote devices; process, via one or more processors, the data; and cause, via the one or more processors, the processed data to be stored in an electronic database.

42. The non-transitory computer-readable medium of aspect 41, wherein the one or more sensors are Internet-of-Things battery shunt devices, and wherein the one or more remote devices are one or more vehicle batteries.

43. The non-transitory computer-readable medium of any one of aspects 41-42, the non-transitory computer-readable medium having stored thereon computer-executable instructions that, when executed, cause a computer to: determine a route of a vehicle corresponding to the one or more vehicle batteries; and cause one or more replacement vehicle batteries to be physically shipped to a service location on the route of the vehicle.

44. The non-transitory computer-readable medium of any one of aspects 41-43, the non-transitory computer-readable medium having stored thereon computer-executable instructions that, when executed, cause a computer to: submit one or more request via an application programming interface (API), the request including at least (i) an indication of state of health of the one or more vehicle batteries and (ii) an indication of state of charge of the one or more vehicle batteries.

45. The non-transitory computer-readable of any one of aspect 41, wherein the one or more sensors are Internet-of-Things food service temperature devices, and wherein the one or more remote devices are food service cauldrons.

46. The non-transitory computer-readable of aspect 41, wherein the one or more sensors are Internet-of-Things temperature sensors and/or Internet-of-Things humidity sensors, and wherein the one or more remote devices are data center devices.

47. The non-transitory computer-readable of any one of aspects 41-46, the non-transitory computer-readable medium having stored thereon computer-executable instructions that, when executed, cause a computer to: receive and/or process the data in real-time or substantially real-time; or receive and/or process the data periodically and/or according to a pre-determined schedule.

48. The non-transitory computer-readable of any one of aspects 41-47, the non-transitory computer-readable medium having stored thereon computer-executable instructions that, when executed, cause a computer to: train one or more machine learning models by processing historical battery performance data; and process the data using one or more trained machine learning models to predict a critical battery condition.

49. The non-transitory computer-readable of any one of aspects 41-49, the non-transitory computer-readable medium having stored thereon computer-executable instructions that, when executed, cause a computer to: generate one or more notifications and/or one or more alerts.

### Additional Considerations

The following considerations also apply to the foregoing discussion. Throughout this specification, plural instances may implement operations or structures described as a single instance. Although individual operations of one or more methods are illustrated and described as separate operations, one or more of the individual operations may be performed concurrently, and nothing requires that the operations be performed in the order illustrated. These and other variations, modifications, additions, and improvements fall within the scope of the subject matter herein.

It should also be understood that, unless a term is expressly defined in this patent using the sentence “As used herein, the term” “is hereby defined to mean . . . ” or a similar sentence, there is no intent to limit the meaning of that term, either expressly or by implication, beyond its plain or ordinary meaning, and such term should not be interpreted to be limited in scope based on any statement made in any section of this patent (other than the language of the claims). To the extent that any term recited in the claims at the end of this patent is referred to in this patent in a manner consistent with a single meaning, that is done for sake of clarity only so as to not confuse the reader, and it is not intended that such claim term be limited, by implication or otherwise, to that single meaning. Finally, unless a claim element is defined by reciting the word “means” and a function without the recital of any structure, it is not intended that the scope of any claim element be interpreted based on the application of 35 U.S.C. § 112 (f).

Unless specifically stated otherwise, discussions herein using words such as “processing,” “computing,” “calculating,” “determining,” “presenting,” “displaying,” or the like may refer to actions or processes of a machine (e.g., a computer) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein any reference to “one aspect” or “an aspect” means that a particular element, feature, structure, or characteristic described in connection with the aspect is included in at least one aspect. The appearances of the phrase “in one aspect” in various places in the specification are not necessarily all referring to the same aspect.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

In addition, use of “a” or “an” is employed to describe elements and components of the aspects herein. This is done merely for convenience and to give a general sense of the invention. This description should be read to include one or at least one and the singular also includes the plural unless it is obvious that it is meant otherwise.

Upon reading this disclosure, those of skill in the art will appreciate still additional alternative structural and functional designs for implementing the concepts disclosed herein, through the principles disclosed herein. Thus, while particular aspects and applications have been illustrated and described, it is to be understood that the disclosed aspects are not limited to the precise construction and components disclosed herein. Various modifications, changes and variations, which will be apparent to those skilled in the art, may be made in the arrangement, operation and details of the method and apparatus disclosed herein without departing from the spirit and scope defined in the appended claims.

1. An Internet-of-Things battery shunt device, comprising:
a shunt member and an outer housing, the shunt member having two protruding wings each having respective annular opening through which battery wires may be passed, and the outer housing comprising:
a circuit board comprising:
an analog-to-digital converter circuit for converting an analog signal to a current measured in amperage;
a thermal resistor circuit for measuring a temperature;
an analog-to-digital converter circuit for measuring a voltage at rest and a voltage at load; and
a header for transmitting the current, the temperature and the voltage.

2. The Internet-of-Things battery shunt device of claim 1, further comprising: a 12-volt to 5-volt power conversion circuit.

3. An Internet-of-Things gateway device, comprising:
a circuit board comprising:
one or more microcontroller units;
one or more inter-integrated circuit interfaces for receiving information; and
a memory having stored thereon instructions that, when executed by the one or more microcontroller units, cause the IoT gateway device to:
receive, via the one or more microcontroller units, at least one set of one or more electro-physical measurements from at least one sensor via at least one of the inter-integrated circuit interfaces;
process the electro-physical measurements; and
transmit the electro-physical measurements to a remote computing device via an electronic network.

4. The Internet-of-Things gateway device of claim 3, wherein the electro-physical measurements include at least voltage and current.

5. The Internet-of-Things gateway device of claim 4, wherein the electro-physical measurements further include at least temperature.

6. The Internet-of-Things gateway device of claim 3, the memory having stored thereon instructions that, when executed by the one or more microcontroller units, cause the IoT gateway device to:
in response to determining that the remote computing device is not reachable via the electronic network, cache the electro-physical measurements in the memory for transmission at a later time.

7. The Internet-of-Things gateway device of claim 3, the memory having stored thereon instructions that, when executed by the one or more microcontroller units, cause the IoT gateway device to:
transmit the electro-physical measurements via MQTT.

8. The Internet-of-Things gateway device of claim 3, wherein at least one of the microcontroller units includes one or both of (i) a Wi-Fi controller, and (ii) a Bluetooth controller.

9. The Internet-of-Things gateway device of claim 6, wherein the at least one of the microcontroller units is an ESP32 microcontroller unit.

10. The Internet-of-Things gateway device of claim 3, wherein the microcontroller units, inter-integrated circuit interfaces, and memory are stored in a pressure-tested waterproof housing.

11. A computing system for collecting state of health and/or state of charge of one or more vehicle batteries, comprising:
a remote computing device;
an electronic network;
an Internet-of-Things gateway device comprising at least one microcontroller unit and one or more memories; and
one or more Internet-of-Things battery shunt devices,
wherein each Internet-of-Things battery shunt device is communicatively coupled to the Internet-of-Things gateway device via a respective annular opening in a housing of the Internet-of-Things gateway device, and
wherein each Internet-of-Things battery shunt device is communicatively coupled to a respective one of the vehicle batteries;
wherein the one or more memories of the Internet-of-Things gateway device include computer-executable instructions that, when executed by the at least one microcontroller unit of the Internet-of-Things gateway device, cause the Internet-of-Things gateway device to:
receive, from the Internet-of-Things gateway device via the electronic network, physical data from at least one of the Internet-of-Things battery shunt devices;
process, via the at least one microcontroller unit, the physical data; and
transmit, via the electronic network, the physical data to the remote computing device.

12. The computing system of claim 11, wherein the electronic network is a cellular network.

13. The computing system of claim 11, wherein the physical data of at least one of the Internet-of-Things battery shunt devices includes at least voltage physical data, current physical data and temperature physical data.

14. The computing system of claim 13, wherein the voltage physical data includes voltage at rest and voltage under load.

15. A computer-implemented method for collecting state of health and/or state of charge of one or more vehicle batteries, comprising:
receiving, in an Internet-of-Things gateway device via an electronic network, physical data from at least one of a plurality of Internet-of-Things battery shunt devices;
processing, via at least one microcontroller unit, the physical data; and
transmitting, via the electronic network, the physical data to a remote computing device.

16. The computer-implemented method of claim 15, wherein the electronic network is a cellular network.

17. The computer-implemented method of claim 15, wherein the physical data of at least one of the Internet-of-Things battery shunt devices includes at least voltage physical data, current physical data and temperature physical data.

18. The computer-implemented method of claim 17, wherein the voltage physical data includes voltage at rest and voltage under load.

19. A non-transitory computer-readable medium having stored thereon computer-executable instructions that, when executed, cause a computer to:
receive, from an Internet-of-Things gateway device via an electronic network, physical data from at least one of a plurality of Internet-of-Things battery shunt devices;
process, via at least one microcontroller unit, the physical data; and
transmit, via the electronic network, the physical data to a remote computing device.

20. The non-transitory computer-readable medium of claim 19, wherein the electronic network is a cellular network.

21-49. (canceled)
